(19) United States
(12) Patent Application Publication
(10) Pub. No.: US 2008/0304183 A1
(43) Pub. Date: Dec. 11, 2008

(54) Flexure for head gimbal assembly with narrow gimbal width in a hard disk drive

(75) Inventors: Haesung Kwon, San Jose, CA (US); Hyung Jai Lee, Cupertino, CA (US)

Correspondence Address: GREGORY SMITH & ASSOCIATES, 3900 NEWPARK MALL ROAD, 3RD FLOOR, NEWARK, CA, 94560, US

(73) Assignee: Samsung Electronics Co., LTD.

(21) Appl. No.: 11/811,853

(22) Filed: Jun. 11, 2007

(51) Int. Cl. H05K 1/09

(52) U.S. Cl. 360/245.3

(57) ABSTRACT

A hard disk drive and head gimbal assembly including a flexure finger with a micro-actuator split of the flexure supporting a micro-actuator control line, leading to minimized gimbal width for the flexure finger about the micro-actuator assembly including the coupled slider and micro-actuators to reduce mechanical vibrations caused by wind off of a rotating disk surface accessed by the slider.

### TECHNICAL FIELD

This invention relates to the flexure of a head gimbal assembly supporting a micro-actuator coupled to a slider in a hard disk drive.

### BACKGROUND OF THE INVENTION

A contemporary hard disk drive rotates its disks at several thousand revolutions per minute. A head gimbal assembly and its micro-actuator assembly (the slider and its coupled micro-actuators) is acted upon by a wind induced by the rotating disk surface near the slider that can move at speeds of thirty or more miles per hour. The various components of the head gimbal assembly are susceptible to the effects of air flow induced vibration. This is particularly true of the flexure finger, which provides most or all of the electrical signaling between the micro-actuator assembly and the rest of the hard disk drive. Also, as the number of signal traces increase this can lead to complicated modes of mechanical resonance. There is a need for head gimbal assemblies reducing the effects of air flow induced vibration, which are stiff enough to minimize other forms of mechanical vibration, including these complicated modes.

### SUMMARY OF THE INVENTION

An embodiment of the invention includes a hard disk drive using a head gimbal assembly configured to reduce mechanical vibrations caused by wind off of the rotating disk surface. The head gimbal assembly includes a slider for accessing a rotating disk surface and at least one micro-actuator coupled to the slider to form a micro-actuator assembly, as well as a flexure finger electrically coupled to the micro-actuator assembly providing at least one micro-actuator control line. The flexure finger includes a micro-actuator flexure split in front of the front edge of the slider separating the flexure finger providing the micro-actuator control line to the micro-actuator. This allows the gimbal width of the flexure finger around the micro-actuator assembly to be minimized, reducing mechanical vibrations caused by wind off the rotating disk surface.

In some embodiments, the flexure finger may include a micro-actuator flex bridge to the flexure finger providing the micro-actuator control line. In other embodiments, the micro-actuator control line may electrically couple to the micro-actuator adjacent to a front edge of the micro-actuator assembly. In still other embodiments, the head gimbal assembly may further include a hinge tongue mechanically supporting the flexure finger providing the micro-actuator control line. In some embodiments, the micro-actuator flexure split may be opposite the hinge tongue from the front edge, or the micro-actuator flexure split may be near a swage point on the hinge. Any combination of these elements may further minimize the gimbal width. The micro-actuator assembly may include at least two of the micro-actuators, which may or may not have separate control lines and may or may not employ a piezoelectric effect.

### BRIEF DESCRIPTION OF THE DRAWINGS

FIG. 1 shows an example plan view of a hard disk drive embodiment of the invention using an embodiment of the head gimbal assembly including a slider to access a rotating disk surface close to the slider trailing edge.

FIG. 2A shows a perspective view of an actuator assembly embodiment of FIG. 1 showing the voice coil motor coupled to the actuator arms and the head gimbal assemblies coupled to the actuator arms.

FIG. 2B shows a side view of an embodiment of the head gimbal assembly of FIGS. 1 and 2A including the slider coupled to a micro-actuator to form a micro-actuator assembly, a flexure finger coupling to the micro-actuator assembly, a front edge and a trailing edge, with the slider supported by an air bearing over the rotating disk surface created by the wind off the rotating disk surface.

FIG. 3A shows a first embodiment of the hard disk drive and the head gimbal assembly with the flexure finger including a micro-actuator flexure split separating the flexure finger providing a micro-actuator control line to a micro-actuator, with the micro-actuator flexure split situated near the front edge of the slider.

FIG. 3B shows a second embodiment of the hard disk drive and the head gimbal assembly with a micro-actuator flexure split situated in front of the front edge of the micro-actuator assembly and the flexure finger further includes a micro-actuator flexure bridge.

FIG. 3C shows a third embodiment similar to that of FIG. 3B, but the head gimbal assembly further includes a hinge with a hinge tongue.

FIG. 3D shows a fourth embodiment where the micro-actuator flexure split is in front of the hinge tongue and adjacent to a swage point of the hinge. The flexure finger providing the micro-actuator control line is supported in part by the hinge tongue. The micro-actuator control line contact is adjacent to the front edge of its micro-actuator.

### DETAILED DESCRIPTION

Disclosed is an embodiment of the invention including a hard disk drive using a head gimbal assembly configured to reduce mechanical vibrations caused by wind off of the rotating disk surface.

The head gimbal assembly includes a slider for accessing a rotating disk surface and at least one micro-actuator coupled to the slider to form a micro-actuator assembly, as well as a flexure finger electrically coupled to the micro-actuator assembly providing at least one micro-actuator control line. The flexure finger includes a micro-actuator flexure split in front of a front edge of the slider separating the flexure finger providing the micro-actuator control line.

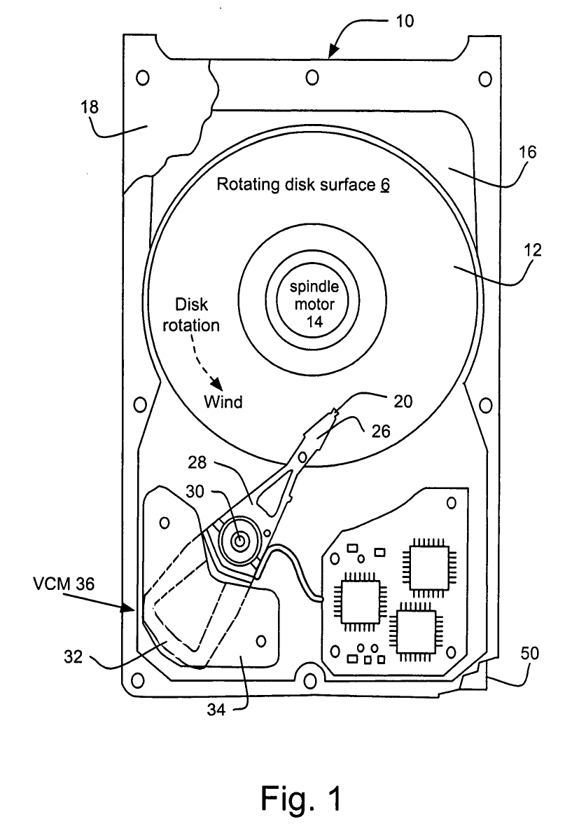

Referring to the drawings, FIG. 1 shows an embodiment of a hard disk drive 10 of the present invention. The hard disk drive may include one or more magnetic disks 12 rotated by a spindle motor 14 to create at least one rotating disk surface 6 which may be accessed to retrieve or store data. The spindle motor may be mounted on a base plate 16. The hard disk drive may further have a cover 18 that encloses the disks 12. A voice coil motor 36 may also be mounted on the disk base 16. The voice coil motor is coupled through an actuator arm 28 to at least one head gimbal assembly 26 to coarsely position a slider 20 over the rotating disk surface.

As the spindle motor 14 rotates the disk 12 rapidly, a wind is induced by the rotating disk surface 6 blowing in essentially the disk rotation direction, and may travel faster than thirty miles per hour through the head gimbal assembly, causing it to vibrate. These vibrations can adversely affect the positioning and performance of the slider 20 in reading and/or writing data. Embodiments of the head gimbal assembly minimize these vibrations through shaping a flexure finger, which will be described shortly.

The voice coil motor 36 operates as follows: The slider 20 is coarsely positioned over the rotating disk surface 6 of the disk 12 by an embedded circuit 50 stimulating the voice coil motor with a time varying electric signal to the voice coil 32 which interacts with at least one fixed magnet 34 to create a torque swinging the actuator arm 28 through the actuator pivot 30, moving the slider across the rotating disk surface. The embedded circuit is often mounted on the disk base opposite and electrically coupled to both the voice coil motor and spindle motor 14.

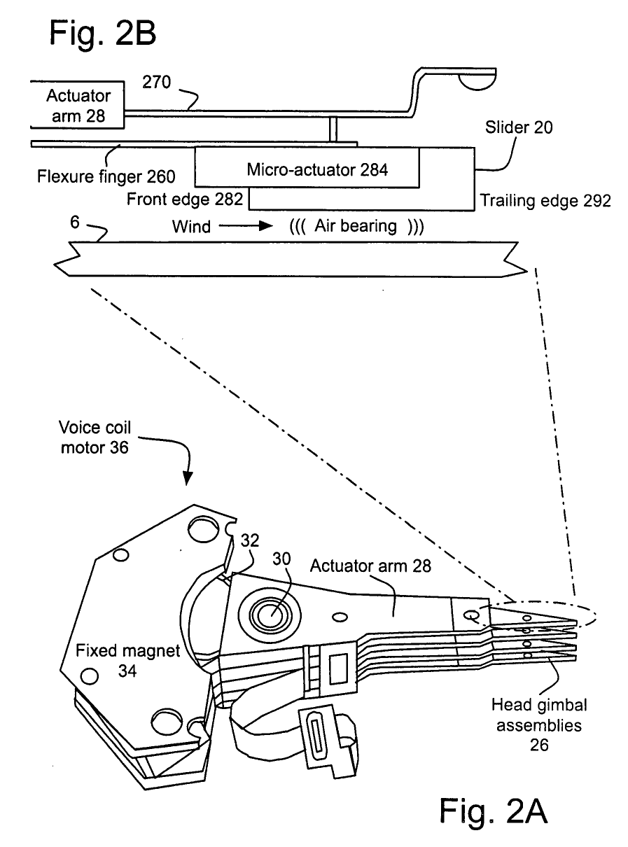

FIG. 2A shows some details of the actuator assembly of FIG. 1 including the voice coil motor 36, the voice coil 32, the fixed magnet 34, the actuator pivot 30 and in this embodiment, multiple actuator arms 28 and multiple head gimbal assemblies 26. The hard disk drive 10 may include more than one disk 12, and may use more than two rotating disk surfaces 6 for data access, as can be seen in this Figure.

FIG. 2B shows some details of an example embodiment of the head gimbal assembly 26 of FIGS. 1 and 2A. The head gimbal assembly may include at least one micro-actuator 284 coupled to the slider 20 to provide fine positioning over the rotating disk surface 6 and a flexure finger 260 coupling to at least one micro-actuator 284 and the slider. The slider flies on an air bearing formed by the wind off of the rotating disk surface 6. The head gimbal assembly is coupled to the actuator arm 28 through a load beam 270. Various embodiments of the head gimbal assembly, and consequently, the hard disk drive 10 make use of special configurations of the flexure finger 260 that narrow the flexure finger about the micro-actuator assembly, which helps minimize vibrations due to the wind. The read head and write head (both not shown) are located near the trailing edge 292 of the slider, which is very close to the rotating disk surface, often less than ten nanometers when the data is to be accessed. The front edge 282 of the slider is opposite the trailing edge, and will be discussed in terms of the flexure finger 260 shortly.

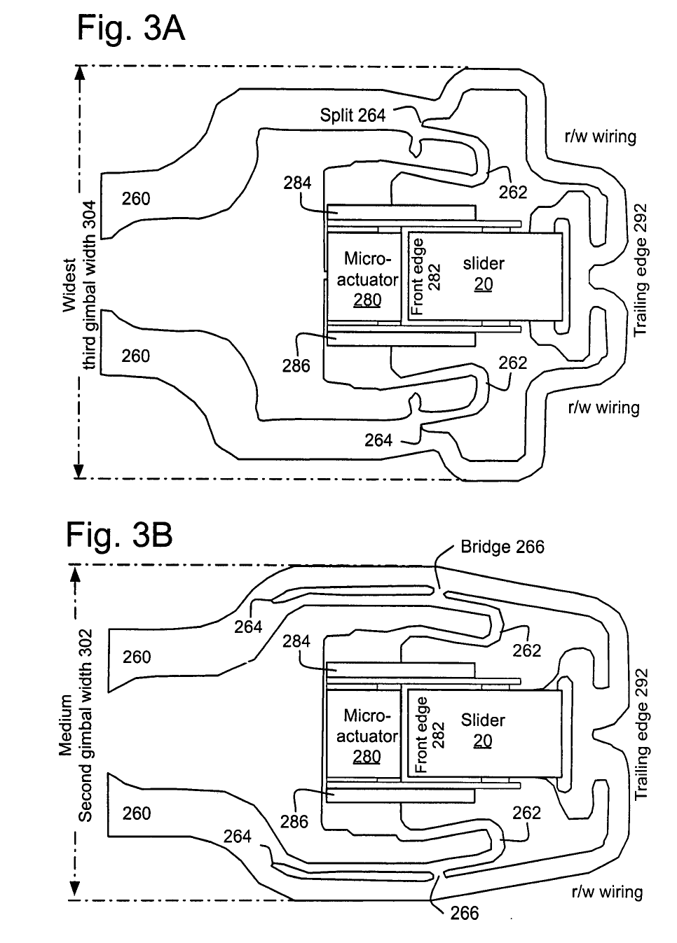

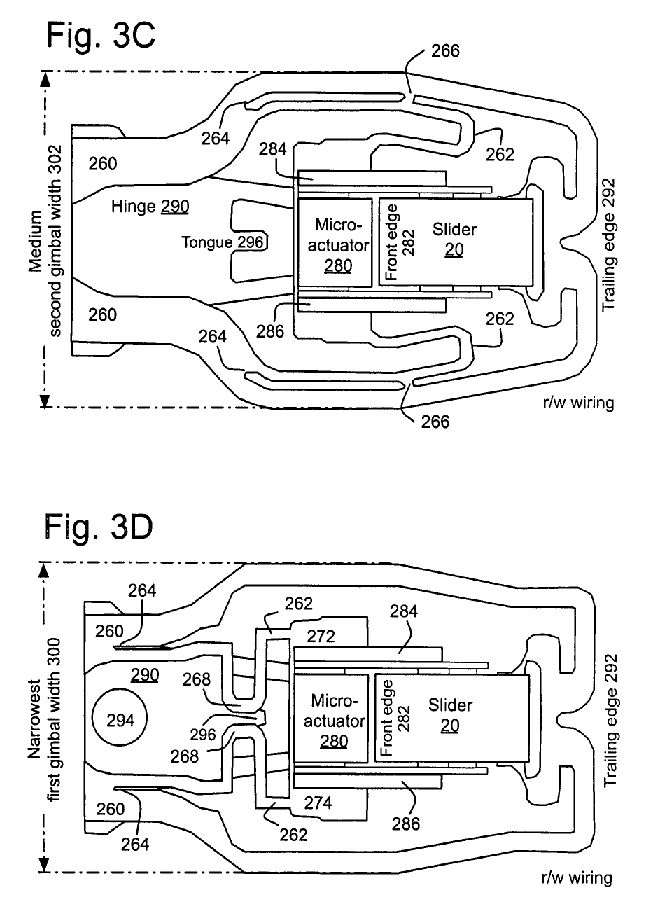

FIGS. 3A to 3D show some example embodiments of the head gimbal assembly 26 of previous Figures where the flexure finger 260 is electrically coupled to the micro-actuator assembly 280 providing at least one micro-actuator control line 262 to a first micro-actuator 284. The flexure finger includes a micro-actuator flexure split 264 separating the flexure finger carrying the micro-actuator control line. In many embodiments of the head gimbal assembly, the micro-actuator assembly 280 further includes a second micro-actuator 286.

The micro-actuators 284 and 286 may employ a piezoelectric effect to alter the position of the slider 20 as shown through the examples of FIGS. 3A to 3D. Alternatively, an electrostatic effect and/or a thermal-mechanical effect may be employed. When the micro-actuator assembly includes at least two of the micro-actuators, they may or may not have separate control lines.

These embodiments of the flexure finger 260 allow the gimbal width of the flexure finger about the micro-actuator assembly 280 to be successively minimized, reducing the induced vibrations from wind created by the rotating disk surface 6. These four embodiments have sufficient stiffness to minimize mechanical modes of resonant vibration, as is summarized in Table One further below.

FIG. 3A shows a first example embodiment of the hard disk drive 10 and the head gimbal assembly 26 including the flexure finger 260 containing the micro-actuator flexure split 264, where the micro-actuator flexure split is situated near the front edge 282 of the slider 20. This configuration creates a gimbal width 304 of flexure finger 260 about the micro-actuator assembly 280, which includes the micro-actuators 284 and 286 coupled to the slider.

FIG. 3B shows a second example embodiment of the hard disk drive 10 and the head gimbal assembly 26 including the flexure finger 260 with its micro-actuator flexure split 266 situated in front of the front edge 282 of the micro-actuator assembly 280 and further including a micro-actuator flexure bridge 266. This configuration can produce a gimbal having a second gimbal width 302 that may be narrower than the first gimbal width 304 of FIG. 3A. A narrower gimbal width may reduce the mechanical vibration experienced by the head gimbal assembly, compared to that of the embodiment seen in FIG. 3A.

FIG. 3C shows a third example embodiment of the hard disk drive 10 and the head gimbal assembly 26 including a flexure finger 260 with its micro-actuator flexure split 264 situated in front of the front edge 282 and the micro-actuator flexure bridge 266, creating essentially the second gimbal width 302 of FIG. 3B. The head gimbal assembly further includes a hinge 290 with a hinge tongue 296.

FIG. 3D shows a fourth example embodiment of the hard disk drive 10 and head gimbal assembly 26 with the micro-actuator flexure split 264 in front of the hinge tongue 296 and near the swage point 294. After the split 264, the flexure finger supported by the hinge tongue 296 is labeled as 268. The micro-actuator control line 262 electrically couples to the micro-actuator 284 adjacent to its front edge, labeled as the micro-actuator control line contact 272. These elements collectively create a third gimbal width 300 which is smaller than the second gimbal width 302. This narrower gimbal width may reduce the mechanical vibration experienced by the head gimbal assembly, compared to that of the embodiments seen in FIGS. 3A, 3B and 3C.

The inventors have performed several numerical simulations which are summarized in the following table:

TABLE ONE
showing four example embodiments and the respective Figures, a couple
of estimates of their pitch stiffness, roll stiffness, lateral stiffness,
inline stiffness and vertical stiffness. Each of these embodiments shows
an acceptable level of stiffness, thus serving to minimize complicated
mechanical resonances.

| | | | Roll | | | |
|---|---|---|---|---|---|---|
| | | Pitch | stiffness | Lateral | Inline | Vertical |
| Embodiment | | Stiffness | (mN- | stiffness | stiffness | stiffness |
| (FIG.) | Remarks | (mN-mm/deg) | mm/deg) | (N/mm) | (N/mm) | (mN/mm) |
| First | First | 1.0 | 1.00 | 1.4 | 20.4 | 18.0 |
| embodiment | estimate | | | | | |
| (FIG. 3A) | Second | 1.1 | 1.03 | 1.4 | 22.9 | 18.0 |
| | estimate | | | | | |
| Second | First | 0.92 | 0.99 | 1.4 | 33.3 | 20.3 |
| embodiment | estimate | | | | | |
| (FIG. 3B) | Second | 0.97 | 1.10 | 1.3 | 36.8 | 20.3 |
| | estimate | | | | | |
| Third | First | 0.66 | 0.68 | 1.3 | 27.4 | 11.9 |
| embodiment | estimate | | | | | |
| (FIG. 3C) | Second | 0.66 | 0.67 | 1.2 | 29.9 | 12.9 |
| | estimate | | | | | |
| Fourth | Copper | 0.97 | 0.59 | 1.1 | 27.4 | 11.9 |
| embodiment | (CU) 15 μm | | | | | |
| | thick | | | | | |
| (FIG. 3D) | CU 10 μm | 0.88 | 0.56 | 1.1 | 27.9 | 11.4 |

Notes on meaning of units:
mN-mm/deg—milli-Newtons multiplied by millimeters per degree of arc
N/mm—Newtons per millimeter
mN/mm—milli-Newtons per millimeter

A second micro-actuator control line 262 may electrically couple to the second micro-actuator 286 adjacent to its front edge, labeled as the second micro-actuator control line contact 274 as further shown in FIG. 3D.

The preceding embodiments provide examples of the invention and are not meant to constrain the scope of the following claims.

What is claimed is:

1. A hard disk drive, comprising:
a disk base;
a spindle motor and a voice coil motor mounted on said disk base;
said spindle motor rotating a disk creating at least one rotating disk surface with data stored on said rotating disk surface;
said voice coil motor coupling through an actuator arm to at least one head gimbal assembly, wherein said head gimbal assembly, comprises
a slider for accessing said rotating disk surface coarsely positioned by said voice coil motor;
at least one micro-actuator coupled to said slider to create a micro-actuator assembly to finely position said slider for accessing said rotating disk surface; and
a flexure finger electrically coupled to said micro-actuator assembly to provide at least one micro-actuator control line to said micro-actuator;
wherein said flexure finger includes a micro-actuator flexure split separating said flexure for reducing mechanical vibration of said slider from wind induced by said rotating disk surface.

2. The hard disk drive of claim 1, wherein said flexure finger further comprises a micro-actuator flex bridge to said flexure finger providing said micro-actuator control line.

3. The hard disk drive of claim 1, wherein said micro-actuator flexure split is in front of a front edge of said micro-actuator assembly.

4. The hard disk drive of claim 1, wherein said micro-actuator control line electrically couples to said micro-actuator adjacent to said front edge of said micro-actuator.

5. The hard disk drive of claim 4, wherein said head gimbal assembly further comprises a hinge with a hinge tongue mechanically supporting said flexure finger providing said micro-actuator control line.

6. The hard disk drive of claim 5, wherein said micro-actuator flexure split is opposite said hinge tongue from said front edge.

7. The hard disk drive of claim 6, wherein said micro-actuator flexure split is near a swage point on said hinge.

8. The hard disk drive of claim 1, wherein said micro-actuator assembly includes at least two of said micro-actuators receiving at least one of said micro-actuator control lines.

9. The hard disk drive of claim 1, wherein said micro-actuator assembly includes at least two of said micro-actuators, each said micro-actuator communicating with a different said micro-actuator control line.

10. A head gimbal assembly for accessing a rotating disk surface in a hard disk drive, comprising:
a slider for accessing said rotating disk surface;
at least one micro-actuator coupled to said slider to create a micro-actuator assembly; and
a flexure finger electrically coupled to said micro-actuator assembly to provide at least one micro-actuator control line to said micro-actuator;
wherein said flexure finger includes a micro-actuator flexure split separating said flexure for reducing mechanical vibration of said slider from wind induced by said rotating disk surface.

11. The head gimbal assembly of claim 10, wherein said flexure finger further comprises a micro-actuator flex bridge to said flexure finger.

12. The head gimbal assembly of claim 10, wherein said flexure finger includes a micro-actuator flexure split in front of a front edge of said slider.

13. The head gimbal assembly of claim 12, wherein said micro-actuator control line electrically couples to said micro-actuator adjacent to said front edge.

14. The head gimbal assembly of claim 13, wherein said head gimbal assembly further comprises a hinge with a hinge tongue mechanically supporting said flexure finger.

15. The head gimbal assembly of claim 14, wherein said micro-actuator flexure split is opposite said hinge tongue from said front edge of said micro-actuator assembly.

16. The head gimbal assembly of claim 15, wherein said micro-actuator flexure split is near a swage point on said hinge.

17. The head gimbal assembly of claim 10, wherein said micro-actuator assembly includes at least two of said micro-actuators communicating with at least one of said micro-actuator control lines.

18. The head gimbal assembly of claim 10, wherein said micro-actuator assembly includes at least two of said micro-actuators, each said micro-actuator communicating with a different said micro-actuator control line.
